(19) United States
(12) Patent Application Publication
(10) Pub. No.: US 2025/0364505 A1
(43) Pub. Date: Nov. 27, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventors: Yasutomo Sakurai, Kawasaki Kanagawa (JP); Yutaka Horie, Mitaka Tokyo (JP); Shugo Suzuki, Hanno Saitama (JP); Hitoshi Imi, Yokohama Kanagawa (JP); Masahiro Koyama, Machida Tokyo (JP)

(21) Appl. No.: 18/827,567

(22) Filed: Sep. 6, 2024

(30) Foreign Application Priority Data
May 21, 2024 (JP) 2024-082686

(51) Int. Cl. H01L 25/11; H01L 23/00; H01L 23/373; H01L 23/535; H02M 1/32; H02M 3/335

(52) U.S. Cl. CPC H01L 25/112; H01L 23/3736; H01L 23/535; H01L 24/16; H01L 24/17; H01L 24/32; H01L 24/73; H02M 1/327; H02M 3/33571; H01L 2224/16155; H01L 2224/16195; H01L 2224/17181; H01L 2224/32225; H01L 2224/32265; H01L 2224/73203; H01L 2924/1203; H01L 2924/1205; H01L 2924/13055; H01L 2924/13064

(57) ABSTRACT

According to one embodiment, a semiconductor device includes: a first conductive layer provided on a substrate; a second conductive layer provided on the substrate and to which a first voltage is supplied; a third conductive layer corresponding to an output node and provided on the substrate between the first conductive layer and the second conductive layer; a first switching device provided above the first conductive layer and including a first terminal to which a second voltage higher than the first voltage is supplied and a second terminal connected to the third conductive layer; and a second switching device provided above the second conductive layer and including a third terminal connected to the third conductive layer and a fourth terminal connected to the second conductive layer.

### CROSS-REFERENCE TO RELATED APPLICATIONS

This application is based upon and claims the benefit of priority from prior Japanese Patent Application No. 2024-082686, filed May 21, 2024, the entire contents of which are incorporated herein by reference.

### FIELD

Embodiments described herein relate generally to a semiconductor device.

### BACKGROUND

Power devices using semiconductor elements are used in various electric apparatuses.

### BRIEF DESCRIPTION OF DRAWINGS

FIG. 1 is a circuit diagram illustrating an example of a circuit configuration of an apparatus including a semiconductor device according to a first embodiment.

FIG. 2 is a cross-sectional view illustrating an example of a structure of the semiconductor device of the first embodiment.

FIG. 3 is a plan view illustrating an example of the structure of the semiconductor device of the first embodiment.

FIG. 4 is a plan view illustrating an example of the structure of the semiconductor device of the first embodiment.

FIG. 5 is a plan view illustrating an example of the structure of the semiconductor device of the first embodiment.

FIG. 6 is a cross-sectional view illustrating an example of a structure of a semiconductor device of a second embodiment.

FIG. 7 is a plan view illustrating an example of the structure of the semiconductor device of the second embodiment.

FIG. 8 is a circuit diagram illustrating an example of a circuit configuration of an apparatus including a semiconductor device according to a third embodiment.

FIG. 9 is a cross-sectional view illustrating an example of a structure of the semiconductor device of the third embodiment.

FIG. 10 is a plan view illustrating an example of the structure of the semiconductor device of the third embodiment.

FIG. 11 is a plan view illustrating an example of the structure of the semiconductor device of the third embodiment.

FIG. 12 is a plan view illustrating an example of the structure of the semiconductor device of the third embodiment.

FIG. 13 is a cross-sectional view illustrating an example of a structure of a semiconductor device of a fourth embodiment.

FIG. 14 is a plan view illustrating an example of the structure of the semiconductor device of the fourth embodiment.

FIG. 15 is a plan view illustrating an example of a structure of a semiconductor device of a fifth embodiment.

FIG. 16 is a plan view illustrating an example of the structure of the semiconductor device of the sixth embodiment.

FIG. 17 is a cross-sectional view illustrating an example of a structure of a modification of a semiconductor device of an embodiment.

### DETAILED DESCRIPTION

In general, according to one embodiment, a semiconductor device includes: a first conductive layer provided on a substrate; a second conductive layer provided on the substrate and to which a first voltage is supplied; a third conductive layer corresponding to an output node and provided on the substrate between the first conductive layer and the second conductive layer; a first switching device provided above the first conductive layer and including a first terminal to which a second voltage higher than the first voltage is supplied and a second terminal connected to the third conductive layer; and a second switching device provided above the second conductive layer and including a third terminal connected to the third conductive layer and a fourth terminal connected to the second conductive layer.

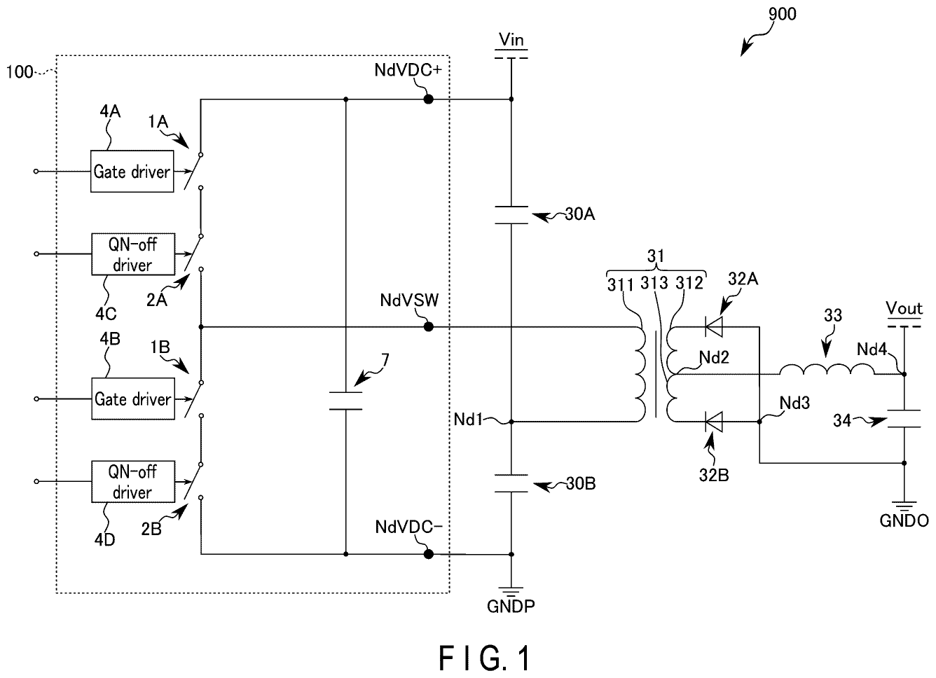

Semiconductor devices according to embodiments will be described with reference to FIGS. 1 to 17. In the following description, elements having the same function and configuration are denoted by the same reference numerals. Further, in each of the following embodiments, in a case where components (for example, circuits, wirings, various voltages and signals, and the like) denoted by reference numerals with numerals/letters at the end for distinguishing are not necessarily distinguished from each other, a description (reference numeral) in which the numerals/letters at the end are omitted is used.

### EMBODIMENTS

### (1) First Embodiment

A semiconductor device according to a first embodiment will be described with reference to FIGS. 1 to 5.

### (a) Circuit Example

FIG. 1 is a circuit diagram illustrating an example of a circuit configuration of an electric apparatus including a semiconductor device according to the present embodiment.

An electric apparatus 900 of FIG. 1 is, for example, a half-bridge converter.

The half-bridge converter 900 includes a semiconductor device 100 of the present embodiment, capacitors 30A and 30B, a transformer 31, diodes 32A and 32B, a coil 33, and a capacitor 34.

The semiconductor device 100 of the present embodiment includes a first node NdVDC+, a second node NdVDC−, and a third node NdVSW. The first node NdVDC+ is electrically connected to a power node Vin on a high potential side (high side) at an input of the half-bridge converter 900. The second node NdVDC− is electrically connected to a power node GNDP on a low potential side (low side) at the input of the half-bridge converter 900. The third node NdVSW is a switching node (output node) in the semiconductor device 100. A positive supply voltage (hereinafter referred to as a voltage Vin) is applied to the power node Vin. The voltage applied to the power node Vin is, for example, a DC voltage. A ground voltage is applied to the power node GNDP. Hereinafter, the power node GNDP is also referred to as a ground node GNDP.

The first node NdVDC+ is a node (voltage node) to which the voltage (for example, the supply voltage) on the high potential side of the semiconductor device 100 is applied. The second node NdVDC− is a node to which the voltage (ground voltage) on the low potential side of the semiconductor device 100 is applied. The voltage applied to the second node NdVDC− is lower than the voltage applied to the first node NdVDC+.

Details of an internal configuration of the semiconductor device 100 will be described below.

One terminal of the capacitor 30A is electrically connected to the power node Vin. The other terminal of the capacitor 30A is electrically connected to a node Nd1.

One terminal of the capacitor 30B is electrically connected to the node Nd1. The other terminal of the capacitor 30B is electrically connected to the ground node GNDP.

The transformer 31 includes a first coil 311, a second coil 312, and a third coil 313. The first coil 311 is a coil on a primary side of the transformer 31. The second and third coils 312 and 313 are coils on a secondary side of the transformer 31. One terminal of the first coil 311 is electrically connected to the switching node NdVSW. The other terminal of the first coil 311 is electrically connected to the node Nd1. One terminal of the second coil 312 is electrically connected to one terminal of the first diode 32A. The other terminal of the second coil 312 is electrically connected to a node Nd2. One terminal of the third coil 313 is electrically connected to the node Nd2. The other terminal of the third coil 313 is electrically connected to one terminal of the second diode 32B. For example, the node Nd2 is an internal node on the secondary side of the transformer 31.

One terminal (for example, a cathode) of the diode 32A is electrically connected to one terminal of the second coil 312. The other terminal (for example, an anode) of the diode 32A is electrically connected to a node Nd3.

One terminal (for example, a cathode) of the diode 32B is electrically connected to the other terminal of the third coil 313. The other terminal (for example, an anode) of the diode 32B is electrically connected to the node Nd3.

One terminal of the coil 33 is electrically connected to the node Nd2. The other terminal of the coil 33 is electrically connected to a node Nd4.

One terminal of the capacitor 34 is connected to the node Nd4. The other terminal of the capacitor 34 is electrically connected to the node Nd3. The voltage of the capacitor 34 is output as an output of the half-bridge converter 900 to an outside of the converter 900. The output voltage of the half-bridge converter 900 is a DC voltage.

The node Nd4 is electrically connected to a power node Vout on the high potential side on an output side of the half-bridge converter 900. The node Nd3 is electrically connected to the power node GNDO on the low potential side on the output side of the half-bridge converter 900. The power node GNDO on the low potential side to which the ground voltage is applied is also referred to as a ground node GNDO.

In the half-bridge converter 900, the semiconductor device 100 of the present embodiment is a power module having a totem pole configuration. More specifically, the semiconductor device 100 of the present embodiment is a switching power module.

The power module 100 includes two switching devices 1 (1A and 1B), two transistors (switching devices) 2 (2A and 2B), a plurality of drivers 4 (4A, 4B, 4C, and 4D), and a capacitor 7.

The plurality of switching devices 1 and the plurality of transistors 2 are electrically connected such that a current path of the switching device 1 is connected in series with a current path of the transistor 2. The switching device 1 and the transistor 2 have a function to open and close a current path between the power node Vin and the ground node GNDP. In the current path between the power node Vin and the ground node GNDP, the switching device 1A and the transistor 2A on the high side have a function to set a current flow direction in the current path by a rectification function. For example, the transistor 2 implements safe operation in a transient state of a power supply of the power module 100.

One terminal of the high-side switching device 1A is electrically connected to the node NdVDC+. The other terminal of the switching device 1A is electrically connected to one terminal of the transistor 2A. The other terminal of the transistor 2A is electrically connected to the node NdVSW. Hereinafter, the high side of the power module 100 is also referred to as a VDC+ side.

One terminal of the low-side switching device 1B is electrically connected to the node NdVSW. The other terminal of the switching device 1B is electrically connected to one terminal of the transistor 2B. The other terminal of the transistor 2B is electrically connected to the node NdVDC−. Hereinafter, the low side of the power module 100 is also referred to as a VDC− side.

In a case where the switching device 1 is an N-channel switching device, one terminal of the switching device 1 is, for example, a drain of a transistor, and the other terminal of the switching device 1 is, for example, a source of the transistor. In a case where the transistor 2 is a P-channel transistor, one terminal of the transistor 2 is, for example, a source of the transistor, and the other terminal of the transistor 2 is, for example, a drain of the transistor.

The switching device 1 is a semiconductor element (hereinafter also referred to as a GaN device) using gallium nitride (GaN). An example of the switching device 1 is a transistor (hereinafter also referred to as a GaN transistor) using GaN. The GaN transistor is, for example, a normally-on transistor (for example, high electron mobility transistor (HEMT)). Note that the switching device 1 may be a field effect transistor using silicon (Si) or silicon carbide (SiC), or an insulated gate bipolar transistor (IGBT).

The transistor 2 is, for example, a normally-off P-channel field effect transistor. The transistor 2 is a metal-oxide-semiconductor (MOS) transistor using Si or SiC. The transistor 2 may be an IGBT.

A quasi-normally-off switching device is formed by a combination of the normally-on switching device 1 and the normally-off transistor 2.

Note that the quasi-normally-off switching device may include a normally-on P-channel switching device 1 and a normally-off N-channel field effect transistor 2.

The drivers 4A and 4B are gate drivers. The gate driver 4A is electrically connected to a gate of the switching device 1A. The gate driver 4B is electrically connected to a gate of the switching device 1B. Each of the gate drivers 4A and 4B controls a gate voltage of the corresponding switching device 1A or 1B. As a result, the operations (on and off) of the switching devices 1 are controlled.

The drivers 4C and 4D are drive circuits that drive the transistors 2A and 2B so as to implement a quasi-normally-off switching device. For example, the drivers 4C and 4D are called quasi-normally-off (QN-off) drivers. The QN-off driver 4C is electrically connected to a gate of the transistor 2A. The QN-off driver 4D is electrically connected to a gate of the transistor 2B. The QN-off drivers 4C and 4D set the corresponding transistors 2A and 2B to an on state and an off state according to the operation of the power module 100 (or the operation of the half-bridge converter 900). As a result, the operation (on and off) of the corresponding transistors 2A and 2B is controlled. The drivers 4C and 4D may be under voltage lock out (UVLO) drivers.

The capacitor 7 is connected between the node NdVDC+ and the node NdVDC−. One terminal of the capacitor 7 is electrically connected to the node NdVDC+. The other terminal of the capacitor 7 is electrically connected to the node NdVDC−. The capacitor 7 is connected in parallel to a current path formed by the switching device 1 and the transistor 2 between the power node Vin and the ground node GNDP. The capacitor 7 functions as a snubber capacitor (snubber circuit) in the power module 100.

The half-bridge converter 900 of FIG. 1 operates according to a known technique as follows.

In the semiconductor device 100 as a power module, on and off of the two transistors 2A and 2B are controlled so that the high-side switching device 1A and the low-side switching device 1B alternately output a current (set to the on state). The power module 100 outputs the current from the switching node NdVSW according to the current from the switching devices 1. The capacitors 30A and 30B are charged or discharged according to the current output from the switching node NdVSW.

An excitation current is generated on the primary side of the transformer 31 according to the charging or discharging of the capacitors 30A and 30B. At timing when both of the two switching devices 1 are set to the off state, the current is generated on the secondary side of the transformer 31.

The capacitor 34 is charged and discharged by the current generated on the secondary side of the transformer 31. As a result, the output voltage of the half-bridge converter 900 is generated.

As described above, by the operation of the semiconductor device 100 of the power module, the half-bridge converter 900 outputs the voltage converted from an input voltage of the power node Vin by voltage conversion (for example, DC-DC conversion) from the power node Vout on the output side and the ground node GNDO.

Note that the electric apparatus 900 is not limited to the half-bridge converter, and may be a converter having another circuit configuration.

### (b) Structural Example

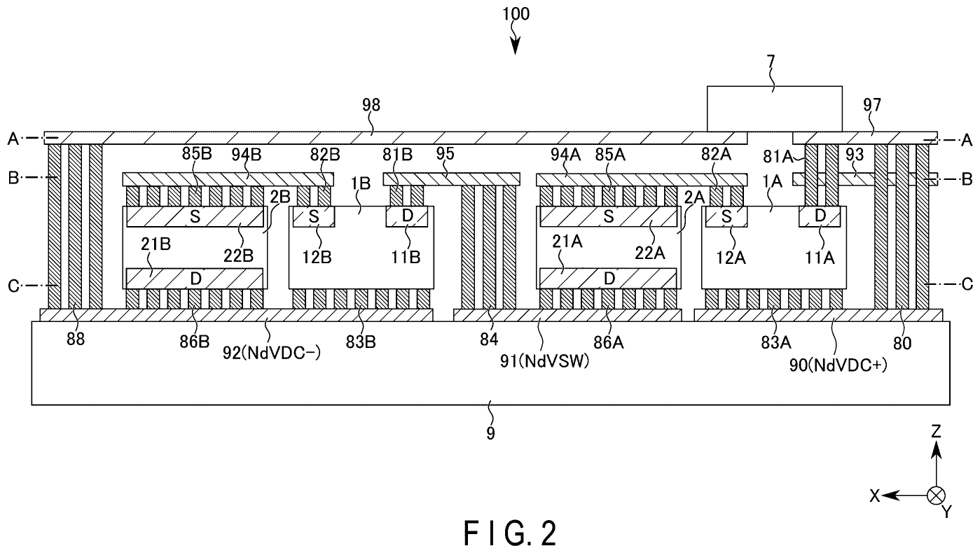

FIGS. 2 to 5 are diagrams illustrating a structural example of the semiconductor device 100 according to the present embodiment.

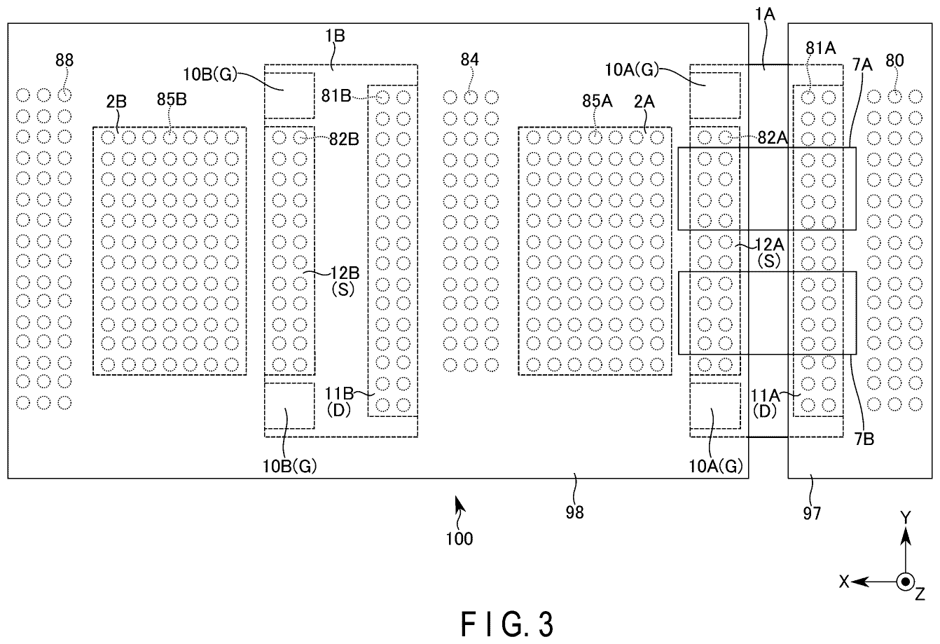

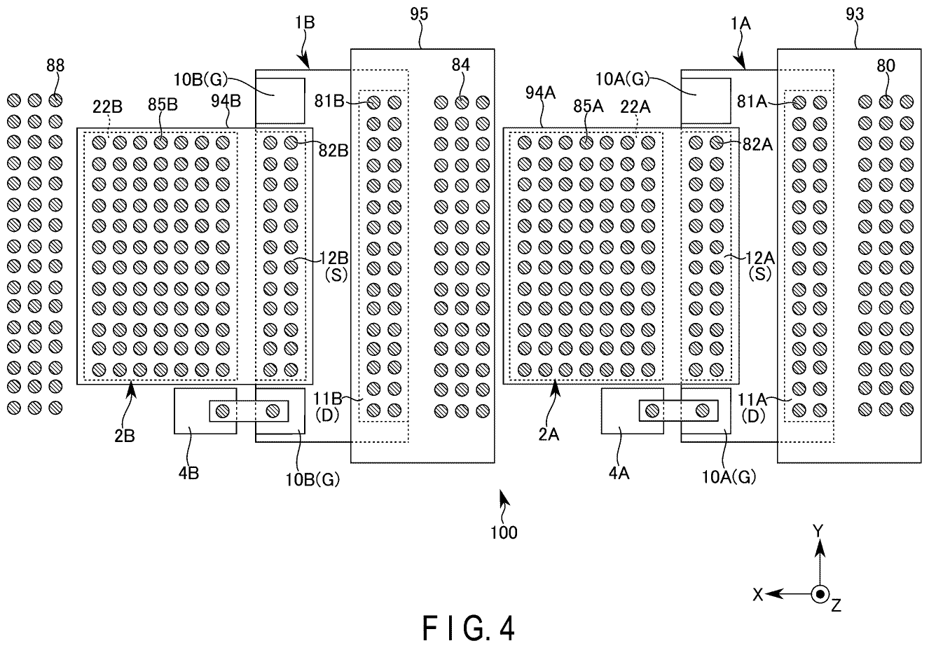

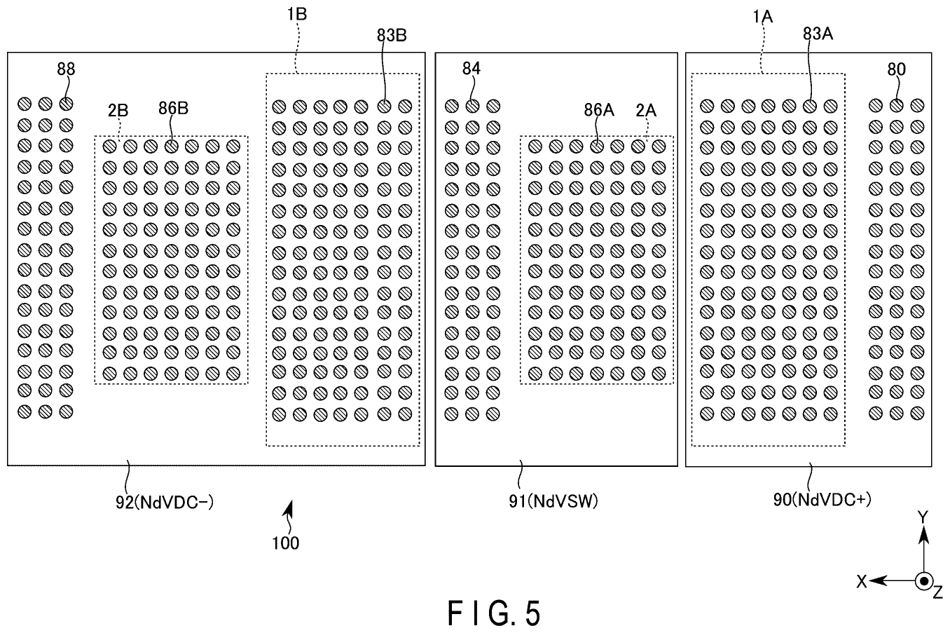

FIG. 2 is a cross-sectional view illustrating a cross-sectional structure of the semiconductor device 100 according to the present embodiment. FIGS. 3 to 5 are plan views illustrating a planar structure of the semiconductor device 100 according to the present embodiment. FIG. 3 illustrates a plane of a layer corresponding to line A-A in FIG. 2 as viewed from an upper surface side of the semiconductor device 100 in a Z direction. FIG. 4 illustrates a plane of a layer corresponding to line B-B in FIG. 2 as viewed from the upper surface side of the semiconductor device 100 in the Z direction. FIG. 5 illustrates a plane of a layer corresponding to line C-C in FIG. 2 as viewed from the upper surface side of the semiconductor device 100 in the Z direction.

As illustrated in FIGS. 2 to 5, the semiconductor device 100 includes the switching devices 1 (1A and 1B), the transistors 2 (2A and 2B), the capacitor 7 (7A and 7B), a plurality of plugs (contacts and connectors) 80, 81 (81A and 81B), 82 (82A and 82B), 83 (83A and 83B), 84, 85 (85A and 86B), 86 (86A and 86B), and 88, and a plurality of conductive layers (interconnects) 90, 91, 92, 93, 94 (94A and 94B), 95, 97, and 98.

The semiconductor device 100 is provided on a surface of a substrate 9. The substrate 9 is a multilayer interconnect substrate (for example, a mother board) including a plurality of multilayered interconnects (not illustrated). The substrate 9 may be a substrate including a single layer of wiring or an insulating substrate. The substrate 9 may be an insulating substrate provided with a heat sink. Hereinafter, the surface of the substrate 9 is also referred to as an XY plane. An X direction is a direction parallel to the XY plane. A Y direction is a direction parallel to the XY plane and intersecting (for example, orthogonal to) the X direction. The Z direction is a direction (for example, a direction perpendicular to the XY plane) intersecting the XY plane.

The switching devices 1 and the transistors 2 are arranged in the same layer (height) in the Z direction.

A semiconductor chip (or semiconductor package) of the plurality of switching devices (GaN transistors) 1 is provided in the semiconductor device 100.

The switching device 1A includes a drain layer (also referred to as a drain electrode) 11A, a source layer (also referred to as a source electrode) 12A, and a gate layer (also referred to as a gate electrode) 10A. The switching device 1B includes a drain layer 11B, a source layer 12B, and the gate layer 10A.

The switching device 1 is a lateral transistor. In the switching devices 1 (1A and 1B) of the lateral transistors, the drain layers 11 (11A and 11B), the source layers 12 (12A and 12B), and the gate layers 10 (10A and 10B) are provided on the front surface side (upper side) of the semiconductor chip of the switching devices 1. Gate layers 13 are provided such that the two gate layers 13 are respectively adjacent to one end and the other end of the source layer 12 in the Y direction. In the switching device 1 that is the lateral GaN transistor, the drain layer 11 is aligned with the source layer 12 in the X direction. A drain current of the switching device 1 flows in a direction (for example, in the X direction) parallel to the surface of the semiconductor chip. A back surface of the semiconductor chip of the switching device 1 is insulated.

The semiconductor chip (or a semiconductor package) of the plurality of transistors (MOS transistors) 2 is provided in the semiconductor device 100.

The transistor 2A includes a drain layer (also referred to as a drain electrode) 21A, a source layer (also referred to as a source electrode) 22A, and a gate layer (also referred to as a gate electrode) (not illustrated). The transistor 2B includes a drain layer 21B, a source layer 22B, and a gate layer.

The transistor 2 is a vertical transistor. In the transistors 2 (2A and 2B) of the vertical transistors, the drain layers 21 (21A and 21B) are provided on the back surface side (lower side) of the semiconductor chip of the transistors 2, and the source layers 22 (22A and 22B) and the gate layers (not illustrated) are provided on the front surface side (upper side) of the semiconductor chip of the transistors 2. In the transistor 2 that is the vertical transistor, the drain layer 21 vertically overlaps the source layer 22 in the Z direction. A drain current of the transistor 2 flows in a direction (Z direction) perpendicular to the surface of the semiconductor chip. For example, the gate layer (not illustrated) is provided on the front surface side of the transistor 2A. Note that the transistor 2 may be a lateral transistor.

The transistor 2A is adjacent to the switching device 1A in the X direction in a space between the plugs 80 and the plugs 84. The transistor 2B is adjacent to the switching device 1B in the X direction in a space between the plugs 84 and the plugs 88. The transistor 2A is provided between the switching device 1A and the switching device 1B in the X direction. The switching device 1B is provided between the transistor 2A and the transistor 2B in the X direction.

The capacitor (snubber capacitor) 7 is provided above the switching device 1A in the Z direction.

As illustrated in FIGS. 2 and 3, the conductive layer 97 and the conductive layer 98 are provided in a layer (layer along line A-A) above the layer in which the switching devices 1 and the transistors 2 are provided. The conductive layers 97 and 98 are layers including (containing) copper (Cu) (for example, Cu layers).

The conductive layer 98 is aligned with the conductive layer 97 in the X direction.

One end of the conductive layer 97 in the X direction overlaps the plurality of plugs 80 in the Z direction.

The conductive layer 97 is electrically connected to the conductive layer 90 on the substrate 9 via the plugs 80 extending in the Z direction. The conductive layer 90 is an electrode of the high-side node NdVDC+ of the power module 100. A positive voltage (VDC+) corresponding to the supply voltage is supplied to the conductive layer 90. The conductive layer 97 is electrically connected to the drain layer 11A of the switching device 1A via the plugs 81A extending in the Z direction. As a result, the positive voltage (VDC+) corresponding to the supply voltage is supplied to the drain layer 11A.

One end of the conductive layer 98 in the X direction overlaps the source layer 12A and the gate layer 10A of the switching device 1A. The other end of the conductive layer 98 in the X direction overlaps the plurality of plugs 88 in the Z direction.

The conductive layer 98 is electrically connected to the conductive layer 92 on the substrate via the plugs 88 extending in the Z direction. The conductive layer 92 is an electrode of the low-side node NdVDC− of the power module 100. A voltage (VDC−) corresponding to the ground voltage is supplied to the conductive layer 92. The voltage supplied to the conductive layer 92 is lower than the voltage supplied to the conductive layer 90.

The dimension of the conductive layer 97 in the Y direction is larger than the dimension of the switching device 1 in the Y direction. The dimension of the conductive layer 98 in the Y direction is larger than the dimension of the switching device 1 in the Y direction.

The plugs 80 are arranged on the conductive layer 90. The plugs 81A are arranged on the drain layer 11A of the switching device 1A. The plugs 88 are arranged on the conductive layer 92. The plugs 80, 81A, and 88 are conductors. The numbers of the plugs 80, 81A, and 88 may be one or more according to the sizes of the plugs.

The semiconductor device 100 includes, for example, electronic components such as the capacitors 7A and 7B. The capacitors 7A and 7B are arranged above the switching device 1A in the Z direction so as to extend over the two conductive layers 97 and 98. One terminals of the capacitors 7A and 7B are electrically connected to the conductive layer 90 via the conductive layer 97 and the plugs 80. The other terminals of the capacitors 7A and 7B are electrically connected to the conductive layer 92 via the conductive layer 98 and the plugs 88. The capacitors 7A and 7B are connected in parallel between the conductive layer 90 as the node NdVDC+ and the conductive layer 92 as the node NdVDC−. Although an example in which the two capacitors 7A and 7B are provided is illustrated, the number of capacitors 7A and 7B is arbitrary. Note that the shape and size of the conductive layer 97 and the shape and size of the conductive layer 98 can be appropriately changed according to the position where the capacitor 7 is arranged and the number of capacitors 7.

As illustrated in FIGS. 2 and 4, the plurality of conductive layers 93, 94A, 94B, and 95 is provided in an intermediate layer between the layers of the conductive layers 97 and 98 and the layer of the switching devices 1. The plurality of conductive layers 93, 94A, 94B, and 95 is arranged in the X direction. The conductive layers 93, 94A, 94B, and 95 are layers including Cu (for example, Cu layers).

The conductive layer 93 is provided below the conductive layer 97 in the Z direction. The conductive layer 93 vertically overlaps the conductive layer 97. One end of the conductive layer 93 covers the drain layer 11A of the switching device 1A in the Z direction. For example, the plugs 80 and the plugs 81A penetrate the conductive layer 93. One end of the conductive layer 93 in the X direction is electrically connected to the conductive layer 90 via the plugs 80. The other end of the conductive layer 93 in the X direction is electrically connected to the drain layer 11A via the plugs 81A. Note that each of the plugs 80 and 81A may be divided into a portion between the conductive layer 93 and the conductive layer 97 and a portion between the conductive layer 93 and the conductive layer 90 without penetrating the conductive layer 93.

The conductive layer 94A is provided below the conductive layer 98 in the Z direction, for example. The conductive layer 94A is provided between the conductive layer 93 and the conductive layer 95 in the X direction. The conductive layer 94A extends from the switching device 1A to the transistor 2A. The conductive layer 94A extends over the source layer 12A of the switching device 1A and the source layer 22A of the transistor 2A. One end of the conductive layer 94A in the X direction is electrically connected to the source layer 12A of the switching device 1A via the plurality of plugs 82A extending in the Z direction. The other end of the conductive layer 94A in the X direction is electrically connected to the source layer 22A provided on the front surface side of the transistor 2A via the plurality of plugs 85A extending in the Z direction. The conductive layer 94A does not vertically overlap the gate layer 10 in the Z direction. Note that the conductive layer 94A may be arranged so as to overlap the conductive layer 97 in the Z direction without overlapping the conductive layer 98 depending on the position of the capacitor 7.

The dimension of the conductive layer 94A in the Y direction is smaller than the dimension of the switching device 1 in the Y direction and larger than the dimension of the transistor 2 in the Y direction.

The plugs 82A are arranged in an array on the source layer 12A of the switching device 1A. The plugs 85A are arranged in an array on the source layer 22A of the transistor 2A. The plugs 82A and 85A are conductors.

The conductive layer 94B is provided below the conductive layer 98 in the Z direction. The conductive layer 94B extends from the switching device 1B to the transistor 2B. The conductive layer 94B extends over the source layer 12B of the switching device 1B and the source layer 22B of the transistor 2B. One end of the conductive layer 94B in the X direction is electrically connected to the source layer 12B of the switching device 1B via the plurality of plugs 82B extending in the Z direction. The other end of the conductive layer 94B in the X direction is electrically connected to the source layer 22B provided on the front surface side of the transistor 2B via the plurality of plugs 85B extending in the Z direction.

The dimension of the conductive layer 94B in the Y direction is smaller than the dimension of the switching device 1 in the Y direction and larger than the dimension of the transistor 2 in the Y direction.

The plugs 82B are arranged in an array on the source layer 12B of the switching device 1B. The plugs 85B are arranged in an array on the source layer 22B of the transistor 2B. The plugs 82B and 85B are conductors.

The conductive layer 95 is provided below the conductive layer 98 in the Z direction. The conductive layer 95 is provided between the conductive layer 94A and the conductive layer 94B in the X direction. The conductive layer 95 extends over the conductive layer 91 on the substrate 9 and the switching device 1B in the Z direction. One end of the conductive layer 95 in the X direction overlaps the conductive layer 91 in the Z direction. The other end of the conductive layer 95 in the X direction overlaps the drain layer 11B of the switching device 1B in the Z direction. Note that the conductive layer 95 may be arranged so as to overlap the conductive layer 97 in the Z direction without overlapping the conductive layer 98 depending on the position of the capacitor 7.

One end of the conductive layer 95 in the X direction is electrically connected to the conductive layer 91 via the plurality of plugs 84 extending in the Z direction. The other end of the conductive layer 95 is electrically connected to the drain layer 11B of the switching device 1B via the plurality of plugs 81B extending in the Z direction.

The plugs 81B are arranged in an array on the drain layer 11B of the switching device 1B. The plugs 84 are arranged in an array on the conductive layer 91. The plugs 84 are provided between the switching device 1B and the transistor 2A in the X direction. The plugs 81B and 84 are conductors.

The gate drivers 4A and 4B are provided in an area on the surface of the substrate 9. The gate drivers 4A and 4B are provided above the substrate 9. For example, the gate drivers 4A and 4B are provided in the same layer (height from the surface of the substrate 9) as the switching devices 1. The gate drivers 4A and 4B are connected to the gate layers 10A and 10B of the switching devices 1A and 1B, respectively. For example, the QN-off drivers 4C and 4D (not illustrated) are provided on the substrate 9, similarly to the gate drivers 4. Note that each driver 4 may be provided on the substrate 9, may be provided on the conductive layer 97 or 98, or may be provided outside the substrate 9 according to a design of the power module 100.

As illustrated in FIGS. 2 and 5, the plurality of conductive layers 90, 91, and 92 are provided in a layer between the switching devices 1 and the substrate 9. The conductive layers 90, 91, and 92 are provided on the substrate 9. The conductive layer 91 is provided between the conductive layer 90 and the conductive layer 92 in the X direction. As described above, the conductive layer 90 is the high-side (+VDC side) electrode (node NdVDC+) of the power module 100, and the conductive layer 92 is the low-side (−VDC side) electrode (node NdVDC−) of the power module 100. Further, the conductive layer 91 is an electrode of the switching node (output node) NdVSW of the power module 100. The conductive layers 90, 91, and 92 are layers including Cu (for example, Cu layers).

The conductive layer 90 is provided below the switching device 1A in the Z direction. One end of the conductive layer 90 in the X direction vertically overlaps a part of the conductive layer 97 in the Z direction. One end of the conductive layer 90 in the X direction is electrically connected to the conductive layer 97 (and the conductive layer 93) via the plugs 80. The other end of the conductive layer 90 in the X direction vertically overlaps the switching device 1A in the Z direction. The plurality of plugs 83A extending in the Z direction is provided between the back surface of the semiconductor chip of the switching device 1A and the other end of the conductive layer 90 in the X direction.

The plugs 83A are arranged on the conductive layer 90. The plugs 83A are conductors. The plugs 83A are in contact with the back surface of the switching device 1A. The back surface of the switching device 1A of the lateral transistor is insulated. Therefore, the plugs 83A do not form a current path between the switching device 1A and the conductive layer 90. The plugs 83A propagates heat generated from the switching device 1A to the conductive layer 90. The number of plugs 83A may be one or more according to the size of the plugs.

The conductive layer 91 is provided below the transistor 2A and a part of the conductive layer 95 in the Z direction. One end of the conductive layer 91 in the X direction vertically overlaps the transistor 2A in the Z direction. One end of the conductive layer 91 in the X direction is electrically connected to the drain layer 21A provided on the back surface side of the transistor 2A via the plugs 86A extending in the Z direction. The plugs 86A are conductors. A drain current of the transistor 2A flows between the transistor 2A and the conductive layer 91 via the plugs 86A.

The plurality of plugs 86A is arranged in an array on the conductive layer 91. The other end of the conductive layer 91 in the X direction vertically overlaps a part of the conductive layer 95 in the Z direction. The other end of the conductive layer 91 in the X direction is electrically connected to the conductive layer 95 via the plugs 84.

In the Z direction, the other end of the conductive layer 91 in the X direction vertically overlaps one end of the conductive layer 95 in the X direction. The other end of the conductive layer 91 in the X direction is electrically connected to the one end of the conductive layer 95 in the X direction via the plugs 84.

A potential of the conductive layer 91 varies according to a switching frequency of the power module 100. The conductive layer 91 is an electrode on a source side of the high-side switching device 1A of the power module 100. The conductive layer 91 is an electrode on a drain side of the low-side switching device 1B of the power module 100.

The conductive layer 92 is provided below the switching device 1B and the transistor 2B in the Z direction. One end of the conductive layer 92 in the X direction vertically overlaps the switching device 1B in the Z direction. The plurality of plugs 83B extending in the Z direction is provided between the back surface of the semiconductor chip of the switching device 1B and one end of the conductive layer 92 in the X direction.

The plurality of plugs 83B is arranged in an array on the conductive layer 92. The plugs 83B are conductors. The plugs 83B are in contact with the back surface of the switching device 1B. The back surface of the switching device 1B of the lateral transistor is insulated. Therefore, the plugs 83B do not form a current path between the switching device 1B and the conductive layer 92. The plugs 83B propagate heat generated from the switching device 1B to the conductive layer 92.

The other end of the conductive layer 92 in the X direction vertically overlaps a part of the conductive layer 98 in the Z direction. The other end of the conductive layer 92 in the X direction is electrically connected to the conductive layer 98 via the plugs 88.

A portion (hereinafter referred to as an intermediate portion) between one end and the other end in the X direction of the conductive layer 92 is provided below the transistor 2B in the Z direction. The intermediate portion of the conductive layer 92 vertically overlaps the transistor 2B in the Z direction. The intermediate portion of the conductive layer 92 is electrically connected to the drain layer 21B provided on the back surface side of the transistor 2B via the plugs 86B extending in the Z direction. The voltage (VDC−) corresponding to the ground voltage is supplied to the drain layer 21B. A drain current of the transistor 2B flows between the transistor 2B and the conductive layer 92 via the plugs 86B.

The plurality of plugs 86B is arranged in an array on the conductive layer 92. The plugs 86B are conductors.

The conductive layer 90 and the conductive layer 92 function as a heat sink against the heat generated by the switching devices 1A and 1B.

The conductive layer 91 as a switching node is isolated from the conductive layers 90 and 92 as heat sinks. The conductive layer 91 does not function as a heat sink.

In the semiconductor device 100 of the present embodiment, the switching devices 1A and 1B that generate heat are provided above the conductive layers 90 and 92 as the voltage nodes via the plugs 83 without being provided on the conductive layer 91 as the switching node.

As described above, in the semiconductor device 100 of the present embodiment, the heat sinks of the switching devices 1 are shared with the voltage nodes NdVDC (NdVDC+ and NdVDC−) 90 and 92 that are substantially not affected by noise.

### (c) Summary

To improve efficiency of the power module including the switching device, it is desired to improve heat dissipation of the switching device. To secure a heat dissipation path of the switching device 1, the conductive layer below the switching device is used as a heat sink. To improve heat dissipation efficiency of the switching device, the area (and volume) of the conductive layer as the heat sink is increased.

As a general tendency, the source of the switching device is set as a reference potential terminal of a switching operation. The potential of the source of the high-side (high potential-side) switching device of the power module varies according to the switching frequency of the switching device. Therefore, the source of the high-side switching device becomes a radiation source that generates large switching noise. The source of the high-side switching device is connected to the switching node of the power module.

In the case where the conductive layer of the switching node is used as the heat sink for heat generation of the switching device 1, noise is applied to the conductive layer of the switching node. In this case, when the area of the conductive layer of the switching node is reduced in order to suppress the noise, heat dissipation characteristics of the switching device are deteriorated.

In the semiconductor device 100 of the present embodiment, the high-side switching device 1A of the power module 100 is provided above the conductive layer 90 as the voltage node NdVDC+. The conductive layer 90 functions as the heat sink of the switching device 1A. As described above, in the present embodiment, the heat dissipation path of the high-side switching device 1A is secured by the conductive layer 90 as the voltage node NdVDC+.

The conductive layer 90 as the heat sink of the high-side switching device 1A is isolated from the conductive layer 91 of the switching node (output node) NdVSW of the power module 100. The conductive layer 90 as the voltage node NdVDC+ is not affected by the noise of the switching device 1A. In addition, the voltage node NdVDC+ does not become a noise generation source for the output of the power module 100. Therefore, in the present embodiment, the heat dissipation characteristics of the switching device 1A can be improved by securing a large area of the conductive layer 90.

Therefore, the semiconductor device 100 of the present embodiment can increase operation efficiency of the semiconductor device.

In the present embodiment, the conductive layer 91 as the switching node NdVSW is not used as the heat sink of the switching device 1A. As a result, the area and volume of the conductive layer 91 as the switching node NdVSW can be reduced. As a result, the semiconductor device 100 according to the present embodiment can reduce the noise generated at the switching node NdVSW.

In the present embodiment, the conductive layer 91 of the switching node NdVSW may satisfy electrical requirements (for example, allowable amounts of current and voltage) in the power module. Therefore, the semiconductor device 100 according to the present embodiment can relatively easily implement countermeasures against the noise of the power module.

In addition, the semiconductor device 100 of the present embodiment can suppress an influence of heat on the switching node NdVSW.

As described above, the semiconductor device 100 according to the present embodiment can achieve improvement in heat dissipation and reduction in noise of the semiconductor device.

Therefore, the semiconductor device 100 of the present embodiment can improve the characteristics of the semiconductor device.

### (2) Second Embodiment

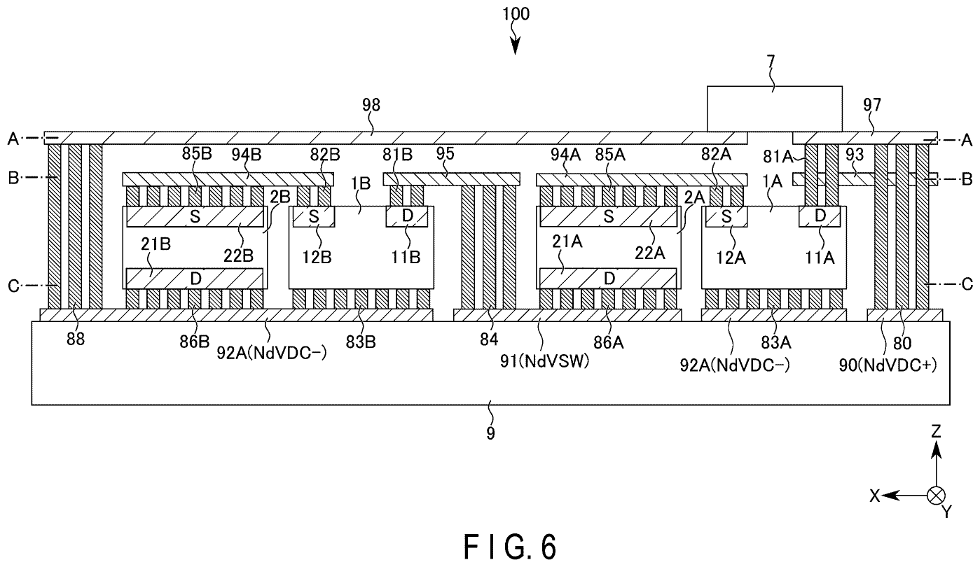

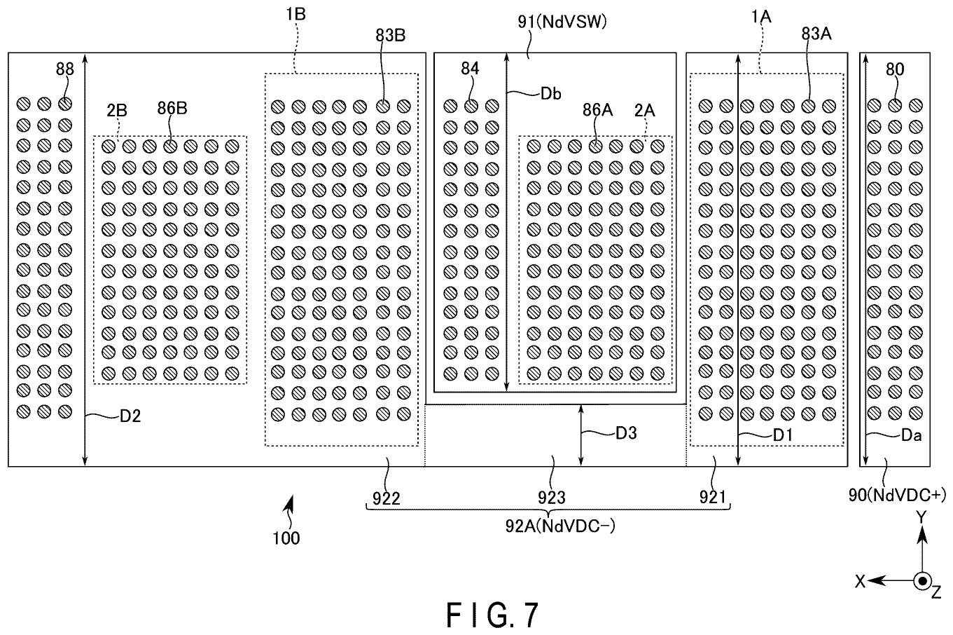

A semiconductor device according to a second embodiment will be described with reference to FIGS. 6 and 7.

FIG. 6 is a cross-sectional view illustrating a cross-sectional structure of a semiconductor device 100 of the present embodiment. FIG. 7 is a plan view illustrating a planar structure of the semiconductor device 100 of the present embodiment. FIG. 7 illustrates a plane of a layer corresponding to line C-C in FIG. 6 as viewed from an upper surface side of the semiconductor device 100 in a Z direction. Note that the planar structure of a layer corresponding to line A-A in FIG. 6 is substantially the same as the example in FIG. 3. Further, the planar structure of a layer corresponding to line B-B in FIG. 6 is substantially the same as the example in FIG. 4.

As illustrated in FIGS. 6 and 7, a high-side switching device (for example, a GaN transistor) 1A of the power module 100 may be provided on a conductive layer 92A corresponding to a low-side voltage node NdVDC− of the power module 100.

The conductive layer 92A has a U-shaped planar shape when viewed from the Z direction. The conductive layer 92A includes a first portion 921, a second portion 922, and a third portion 923. The first portion 921 is continuous with the second portion 922 via the third portion 923.

The switching device 1A is provided above the first portion 921 in the Z direction. Plugs 83A are provided between a back surface of the switching device 1A and the first portion 921. The switching device 1A is electrically isolated from the first portion 921. A current path through the plugs 83A is not formed between the switching device 1A and the first portion 921.

A switching device 1B and a transistor 2B are provided above the second portion 922 in the Z direction. Plugs 83B are provided between a back surface of the switching device 1B and the second portion 922. The switching device 1B is electrically isolated from the second portion 922. A current path through the plugs 83B is not formed between the switching device 1B and the second portion 922. Plugs 86B are provided between a back surface of the transistor 2B and the second portion 922. A drain layer 21B on the back surface of the transistor 2B is electrically connected to the second portion 922 via the plugs 86B. A drain current of the transistor 2B flows between the transistor 2B and the second portion 922 via the plugs 86B.

The third portion (coupling portion) 923 is provided between the first portion 921 and the second portion 922 in an X direction. The third portion 923 couples the first portion 921 to the second portion 922. The third portion 923 is adjacent to one end in the Y direction of a conductive layer 91 of a switching node NdVSW in the Y direction. The third portion 923 electrically connects the first portion 921 to the second portion 922.

A dimension D3 of the third portion in the Y direction is smaller than a dimension D1 of the first portion 921 in the Y direction and a dimension D2 of the second portion 922 in the Y direction. The dimension D2 is substantially equal to the dimension D1. For example, a dimension Da of a conductive layer 90 in the Y direction is equal to the dimensions D1 and D2 and larger than the dimension D3. For example, a dimension Db of the conductive layer 91 in the Y direction is larger than the dimension D3 and smaller than the dimensions D1 and D2. Note that the dimension Da may be equal to or smaller than the dimension D3 depending on a design of a layout of each conductive layer.

As described above, in the semiconductor device 100 of the present embodiment, the high-side switching device 1A of the power module 100 is provided on the conductive layer 92 of the low-side voltage node NdVDC− functioning as a heat sink. Also in this case, the semiconductor device 100 of the present embodiment can obtain substantially the same effects as the effects of the other embodiments.

In addition, in the present embodiment, the conductive layer 91 of the switching node NdVSW is surrounded by the conductive layer 92 of the voltage node NdVDC− on a low potential side (ground side). The conductive layer 92 functions as an electrical shield (ground guard) for the conductive layer 91. As a result, the shielding of the switching node NdVSW of the power module 100 is relatively easily implemented. As a result, the semiconductor device 100 of the present embodiment can further reduce an influence of noise of the switching node NdVSW.

As described above, the semiconductor device 100 of the second embodiment can improve the characteristics of the semiconductor device.

### (3) Third Embodiment

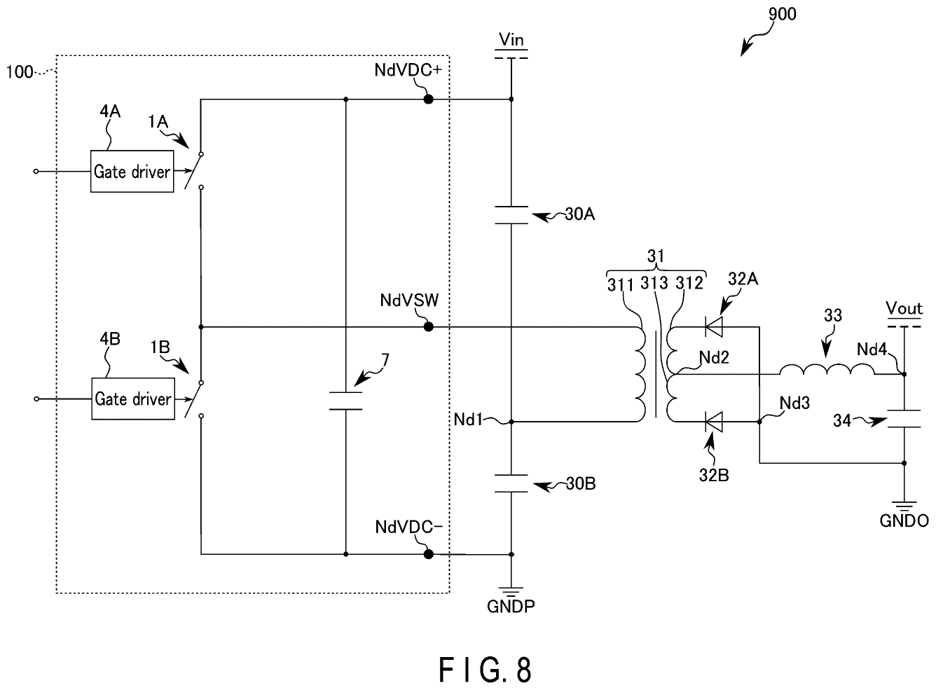

A semiconductor device according to a third embodiment will be described with reference to FIGS. 8 to 12.

### (a) Circuit Example

FIG. 8 is a circuit diagram illustrating a circuit configuration of a semiconductor device 100 of the present embodiment.

In a case where a switching device 1 is a normally-off transistor, the power module 100 having a totem pole configuration may not include a field effect transistor for forming a quasi-normally-off switching device.

As illustrated in FIG. 8, the power module 100 includes two switching devices 1. The switching device 1 is a normally-off transistor.

One end of a switching device 1A is electrically connected to a high-side node NdVDC+ of the power module 100. The other end of the switching device 1A is electrically connected to a switching node NdVSW of the power module 100.

One end of a switching device 1B is electrically connected to the switching node NdVSW. The other end of the switching device 1B is electrically connected to a low-side node NdVDC− of the power module 100.

For example, the switching device 1 is a normally-off field effect transistor (MOS transistor) using Si or SiC. Note that the switching device 1 may be a normally-off transistor using GaN.

A half-bridge converter 900 including the semiconductor device 100 of FIG. 8 is driven by a known operation.

### (b) Structural Example

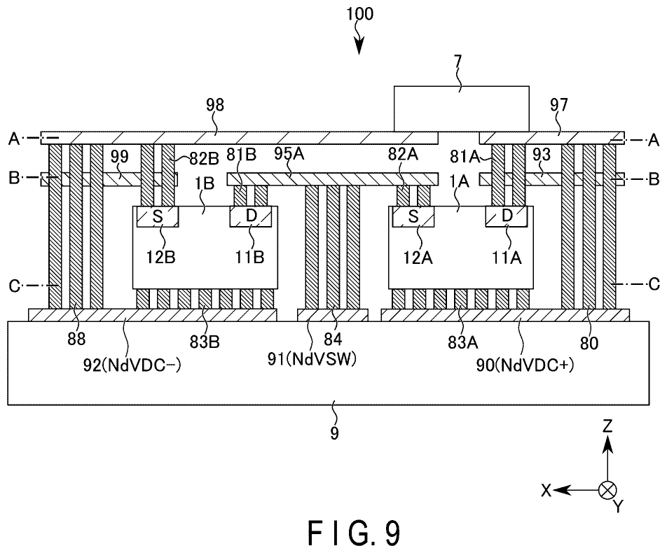

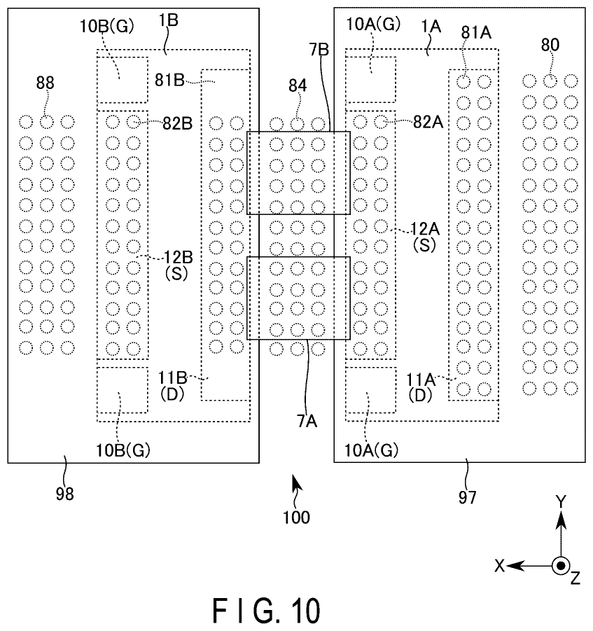

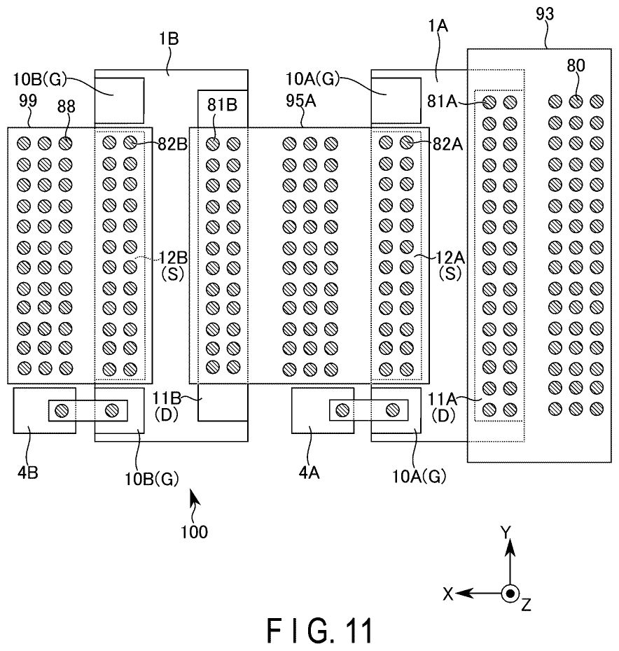

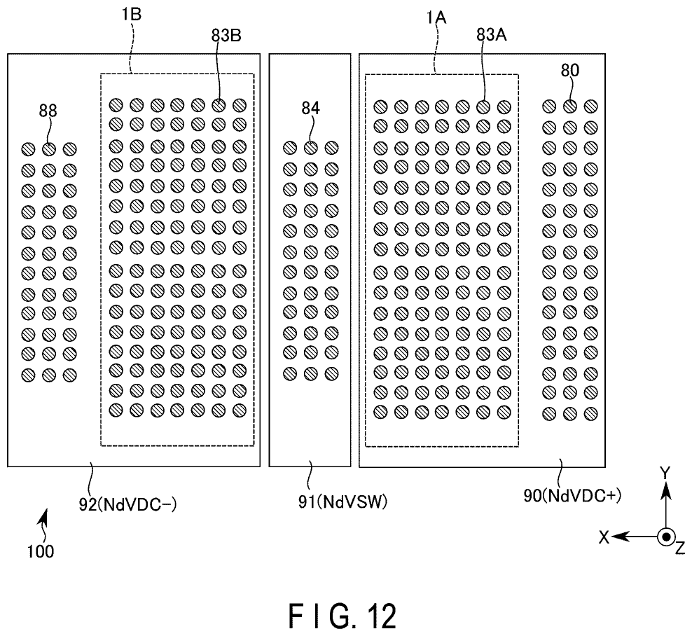

FIGS. 9 to 12 are diagrams illustrating a structural example of the semiconductor device 100 according to the present embodiment. FIG. 9 is a cross-sectional view illustrating a cross-sectional structure of the semiconductor device 100 of the present embodiment. FIGS. 10 to 12 are plan views illustrating a planar structure of the semiconductor device 100 according to the present embodiment. FIG. 10 illustrates a plane of a layer corresponding to line A-A in FIG. 9 as viewed from an upper surface side of the semiconductor device 100 in a Z direction. FIG. 11 illustrates a plane of a layer corresponding to line B-B in FIG. 9 as viewed from the upper surface side of the semiconductor device 100 in the Z direction. FIG. 12 illustrates a plane of a layer corresponding to line C-C in FIG. 9 as viewed from the upper surface side of the semiconductor device 100 in a Z direction.

As illustrated in FIGS. 9 to 12, the switching device 1A is provided between plugs 80 and plugs 84 in an X direction. The switching device 1B is provided between the plugs 84 and plugs 88 in the X direction.

Conductive layers 97 and 98 are provided above the switching devices 1A and 1B in the Z direction. The conductive layer 97 extends from a drain layer 11A of the switching device 1A to a region where the plugs 80 are provided in a conductive layer 90 in the X direction. The conductive layer 98 extends from a source layer 12A of the switching device 1A to a region where the plugs 88 are provided in a conductive layer 92 in the X direction. The conductive layer 98 is electrically connected to a source layer 12B of the switching device 1B via plugs 82B. Note that shape and size of the conductive layer 97 and shape and size of the conductive layer 98 can be appropriately changed according to a position where a capacitor 7 is arranged.

Conductive layers 95A and 99 are provided in a layer between the conductive layer 98 and a surface of the switching device 1 in the Z direction. The conductive layer 95A is adjacent to a conductive layer 93 in the X direction. The conductive layers 95A and 99 vertically overlap the conductive layer 98 in the Z direction. The conductive layer 95A extends between the source layer 12A of the switching device 1A and a drain layer 11B of the switching device 1B via above a conductive layer 91 in the Z direction.

One end of the conductive layer 95A in the X direction is electrically connected to the source layer 12A of the switching device 1A via plugs 82A. The other end of the conductive layer 95A in the X direction is electrically connected to the drain layer 11B of the switching device 1B via plugs 81B. A portion (intermediate portion) between two end portions of the conductive layer 95A is electrically connected to the conductive layer 91 via the plugs 84.

A dimension of the conductive layer 95A in a Y direction is smaller than the dimension of the conductive layer 93 in the Y direction. The dimension of the conductive layer 99 in the Y direction is substantially equal to the dimension of the conductive layer 95A in the Y direction. Note that the dimension of the conductive layer 95A in the Y direction may be equal to or larger than the dimension of the conductive layer 93 in the Y direction.

The conductive layer 99 is adjacent to the conductive layer 95A in the X direction. One end of the conductive layer 99 in the X direction vertically overlaps the source layer 12B of the switching device 1B in the Z direction. The plugs 82B penetrate one end region of the conductive layer 99 in the X direction. The plugs 88 penetrate the other end region of the conductive layer 99 in the X direction.

One end of the conductive layer 99 in the X direction is electrically connected to the source layer 12B of the switching device 1B via plugs 82B. The other end of the conductive layer 99 in the X direction is electrically connected to the conductive layer 92 via the plugs 88. As a result, a voltage (VDC−) corresponding to a ground voltage is supplied to the source layer 12B.

Note that the plugs 82B may be divided into a portion between the conductive layer 98 and the conductive layer 99 and a portion between the conductive layer 99 and the source layer 12B without penetrating the conductive layer 99. The plugs 88 may be divided into a portion between the conductive layer 98 and the conductive layer 99 and a portion between the conductive layer 92 and the conductive layer 99 without penetrating the conductive layer 99.

In the present embodiment, the switching device 1A is provided above the conductive layer 90 as the high-side node NdVDC+ via plugs 83A. The conductive layer 90 and the plugs 83A function as a heat sink of the switching device 1A.

As a result, even in a case where the semiconductor device 100 is formed using the normally-off switching device 1, the semiconductor device 100 of the present embodiment can obtain substantially the same effects as the effects of the other embodiments.

Therefore, the semiconductor device 100 of the third embodiment can improve characteristics of the semiconductor device.

### (4) Fourth Embodiment

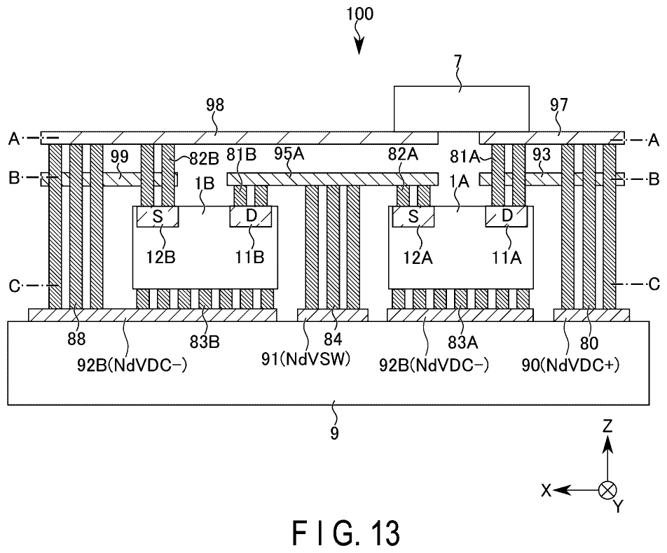

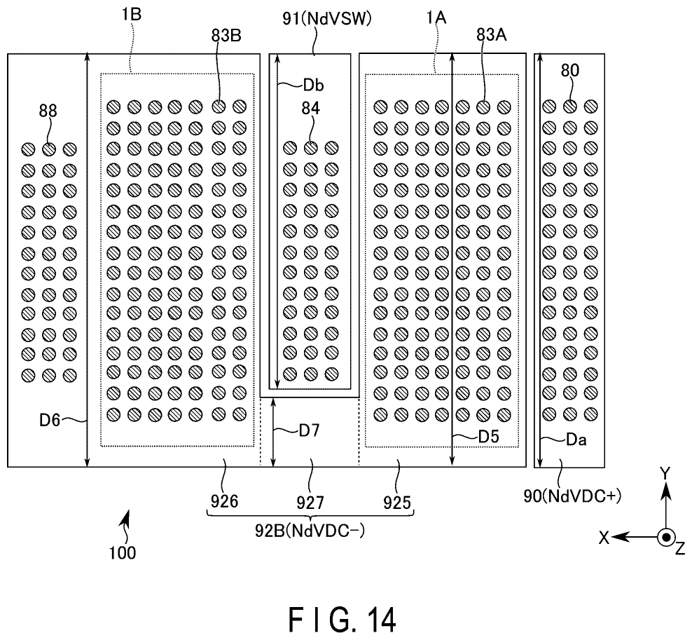

A semiconductor device according to a fourth embodiment will be described with reference to FIGS. 13 and 14.

FIG. 13 is a cross-sectional view illustrating a cross-sectional structure of a semiconductor device 100 of the present embodiment. FIG. 14 is a plan view illustrating a planar structure of the semiconductor device 100 of the present embodiment. FIG. 14 illustrates a plane of a layer corresponding to line C-C in FIG. 13 as viewed from an upper surface side of the semiconductor device 100 in a Z direction. Note that the planar structure of a layer corresponding to line A-A in FIG. 13 is substantially the same as the example in FIG. 10. Further, the planar structure of a layer corresponding to line B-B in FIG. 13 is substantially the same as the example in FIG. 11.

As illustrated in FIGS. 13 and 14, a high-side switching device (for example, a GaN transistor) of the power module 100 may be provided on a conductive layer 92B of a low-side voltage node NdVDC− of the power module 100.

The conductive layer 92B has a U-shaped planar shape when viewed from the Z direction. The conductive layer 92B includes a first portion 925, a second portion 926, and a third portion 927.

A switching device 1A is provided above the first portion 925 in the Z direction. Plugs 83A are provided between a back surface of the switching device 1A and the first portion 925. The switching device 1A is electrically isolated from the first portion 925. A current path through the plugs 83A is not formed between the switching device 1A and the first portion 925.

A switching device 1B is provided above the second portion 926 in the Z direction. Plugs 83B are provided between a back surface of the switching device 1B and the second portion 926. The switching device 1B is electrically isolated from the second portion 926. A current path through the plugs 83B is not formed between the switching device 1B and the second portion 926.

The third portion (coupling portion) 927 is provided between the first portion 925 and the second portion 926 in an X direction. The third portion 927 is adjacent to one end in the Y direction of a conductive layer 91 of a switching node NdVSW in a Y direction. The third portion 927 connects the first portion 925 to the second portion 926.

A dimension D7 of the third portion 927 in the Y direction is smaller than a dimension D5 of the first portion 925 in the Y direction and a dimension D6 of the second portion 926 in the Y direction. The dimension D6 is substantially equal to the dimension D5. For example, a dimension Da of a conductive layer 90 in the Y direction is equal to the dimensions D5 and D6 and larger than the dimension D7. For example, a dimension Db of the conductive layer 91 in the Y direction is larger than the dimension D7 and smaller than the dimensions D5 and D6. Note that the dimension Db may be equal to or smaller than the dimension D7. The dimension Db may be equal to or larger than the dimensions D5 and D6.

In the semiconductor device 100 of the present embodiment, the high-side switching device 1A of the power module 100 is provided on a conductive layer 92 of the low-side voltage node NdVDC− that functions as a heat sink. Also in this case, the semiconductor device 100 of the present embodiment can obtain substantially the same effects as the effects of the other embodiments.

In addition, the semiconductor device 100 of the present embodiment can further reduce noise of the conductive layer 91 of the switching node NdVSW by shielding by the conductive layer 91 of the voltage node NdVDC− on a low potential side.

As described above, the semiconductor device 100 of the fourth embodiment can improve characteristics of the semiconductor device.

### (5) Fifth Embodiment

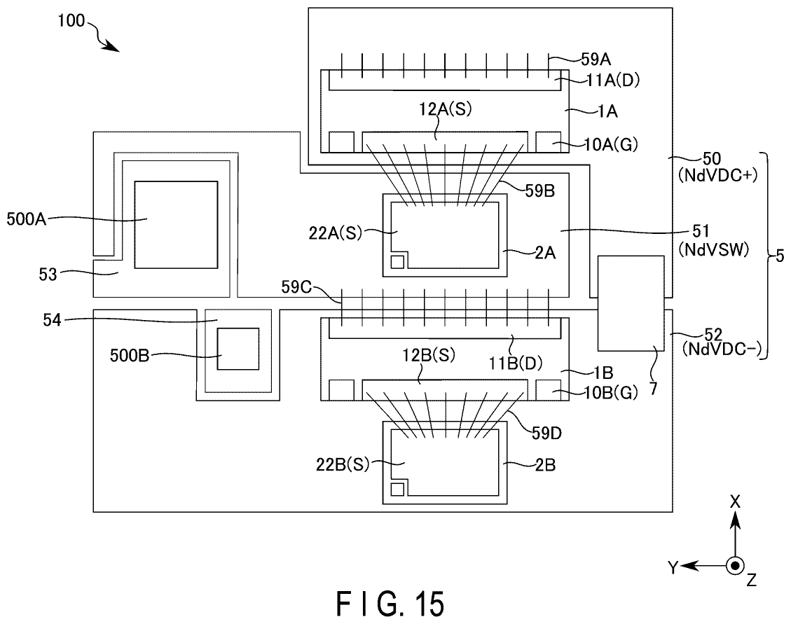

A semiconductor device according to a fifth embodiment will be described with reference to FIG. 15.

FIG. 15 is a plan view illustrating a structural example of a semiconductor device 100 of the present embodiment.

The semiconductor device 100 of FIG. 15 includes a lead frame 5 as a substrate on which a switching device 1 is mounted. The switching device 1 and a transistor 2 are provided on the lead frame 5.

The lead frame 5 includes a plurality of lead layers 50, 51, and 52. The lead layers 50, 51, and 52 are conductive layers (for example, Cu layers).

The lead layer 50 corresponds to an electrode of a high-side node NdVDC+ of the power module 100. The lead layer 51 corresponds to an electrode of a switching node NdVSW of the power module 100. The lead layer 52 corresponds to an electrode of a low-side node NdVDC− of the power module 100.

For example, the lead frame 5 includes lead layers 53 and 54. The lead layers 53 and 54 are conductive layers. A certain electronic component 500A is provided on the lead layer 53. The electronic component 500A is electrically connected to the lead layer 53 and another lead layer by a bonding wire (not illustrated) or a conductive adhesive (not illustrated). A certain electronic component 500B is provided on the lead layer 54. The electronic component 500B is electrically connected to the lead layer 54 and another lead layer by a bonding wire (not illustrated) or a conductive adhesive (not illustrated). The electronic components 500A and 500B are semiconductor devices such as drivers, passive elements such as capacitors, or the like.

A high-side switching device 1A is provided on the lead layer 50 corresponding to the node NdVDC+ via an insulating adhesive layer (not illustrated). A transistor 2A is provided on the lead layer 51 corresponding to the node NdVSW. A drain layer 11A of the switching device 1A is electrically connected to the lead layer 50 via a bonding wire 59A. A source layer 12A of the switching device 1A is electrically connected to a source layer 22A of the transistor 2A via a bonding wire 59B. The drain layer (not illustrated) of the transistor 2A is electrically connected to the lead layer 51 via a solder layer (not illustrated) provided between a back surface of the transistor 2A and the lead layer 51.

A low-side switching device 1B and a transistor 2B are provided on the lead layer 52 corresponding to the node NdVDC−. A drain layer 11B of the switching device 1B is electrically connected to the lead layer 51 via a bonding wire 59C. For example, an insulating adhesive layer (not illustrated) is provided between a back surface of the switching device 1B and the lead layer 52. A source layer 12B of the switching device 1B is electrically connected to a source layer 22B of the transistor 2B via a bonding wire 59D. The drain layer (not illustrated) of the transistor 2A is electrically connected to the lead layer 52 via a solder layer (not illustrated) provided between a back surface of the transistor 2A and the lead layer 51.

The lead layers 50 and 52 function as heat sinks against heat generated by the switching devices 1A and 1B.

For example, a capacitor 7 is provided on the lead layers 50 and 52 so as to extend over the two lead layers 50 and 52. The capacitor 7 is a snubber capacitor.

Note that, in a case where the switching device 1 is a normally-off transistor, the transistor 2 for forming the quasi-normally-off switching device may not be provided on the lead frame. In this case, the source layer 12A of the switching device 1A is electrically connected to the lead layer 51 via the wire 59B, and the source layer 12B of the switching device 1B is electrically connected to the lead layer 52 via the wire 59D.

As described above, in the semiconductor device 100 of the present embodiment, the switching device 1 is provided on the lead frame 5. The high-side switching device 1A of the power module 100 is arranged on the lead layer 50 corresponding to the high-side voltage node NdVDC+ among the plurality of lead layers 50, 51, and 52 in the lead frame 5.

As a result, the semiconductor device 100 of the present embodiment can obtain substantially the same effects as the effects of the other embodiments.

Therefore, the semiconductor device 100 of the fifth embodiment can improve characteristics of the semiconductor device.

### (6) Sixth Embodiment

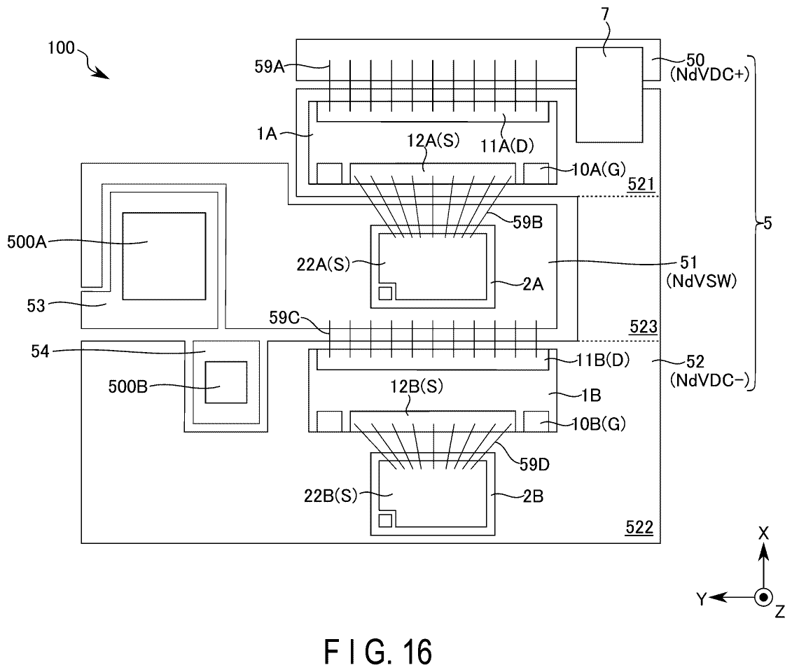

A semiconductor device according to a sixth embodiment will be described with reference to FIG. 16.

FIG. 16 is a plan view illustrating a structural example of a semiconductor device 100 of the present embodiment.

As illustrated in FIG. 16, a high-side switching device 1A of the power module 100 may be provided on a lead layer 52 of a low-side node NdVDC− of the power module 100.

The lead layer 52 includes a first portion 521, a second portion 522, and a third portion 523. The first portion 521 and the second portion 522 sandwich a lead layer 51 in the X direction. The first portion 521 is adjacent to the lead layer 51 at one end of the lead layer 51 in the X direction. The second portion 522 is adjacent to the lead layer 51 at the other end of the lead layer 51 in the X direction. The third portion 523 is provided between the first portion 521 and the second portion 522 in the X direction. The third portion 523 is adjacent in the Y direction to the lead layer 51 at one end of the lead layer 51 in the Y direction.

A lead layer 50 corresponding to a high-side node NdVDC+ is adjacent to the first portion 521 of the lead layer 51 in the X direction. For example, switching devices and other constituent elements are not provided on a lead layer 50. The lead layer 50 is electrically connected to a drain layer 11A of the switching device 1A via a wire 59A.

Note that, also in the present embodiment, in a case where the switching device 1 is a normally-off transistor, a transistor 2 for forming the quasi-normally-off switching device may not be provided on a lead frame.

In the switching device 1 on a lead frame 5 of the semiconductor device 100 of the present embodiment, the high-side switching device 1A of the power module 100 is provided on the lead layer 52 of the low-side voltage node NdVDC− functioning as a heat sink. Also in this case, substantially the same effects as the effects of the other embodiments can be obtained.

Therefore, the semiconductor device 100 of the sixth embodiment can improve characteristics of the semiconductor device.

### (7) Modification

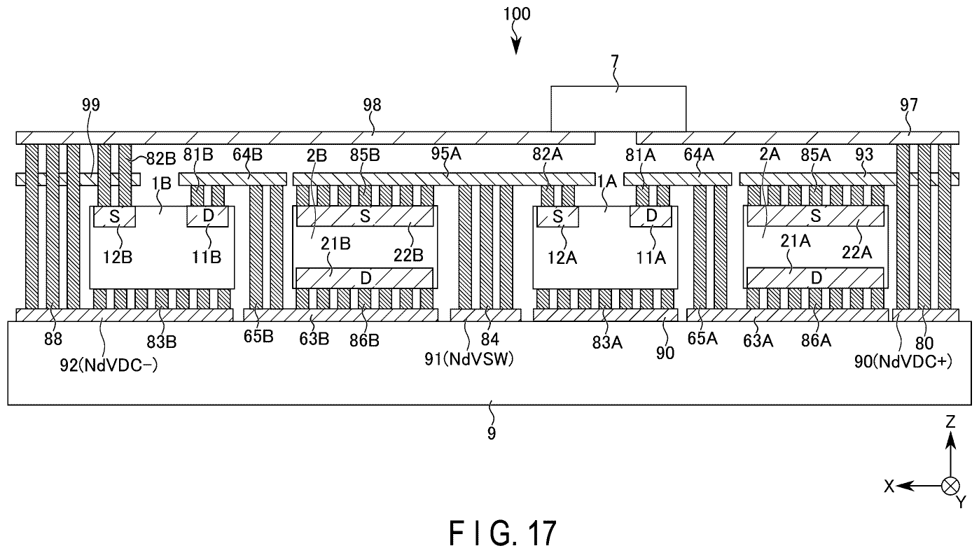

A modification of the semiconductor device of the embodiment will be described with reference to FIG. 17.

FIG. 17 is a cross-sectional view illustrating a cross-sectional structure of a modification of the semiconductor device 100 of the present embodiment.

As illustrated in FIG. 17, in the semiconductor device 100 of the embodiment, the transistor 2A may be connected between the switching device 1A and the high-side voltage node NdVDC+, and the transistor 2B may be connected between the switching device 1B and the switching node NdVSW.

The semiconductor device 100 of the modification further includes conductive layers 63A, 63B, 64A, and 64B and plugs 65A and 65B.

The conductive layers 63A and 63B are provided on the substrate 9. For example, the conductive layer 63A is provided between the first portion and the second portion of the conductive layer 90 in the X direction. The conductive layer 63B is provided between the conductive layer 91 and the conductive layer 92 in the X direction.

The conductive layers 64A and 64B are provided in the layer in which the conductive layers 93, 95A, and 99 are provided. The conductive layer 64A is electrically connected to the drain layer 11A of the switching device 1A via the plugs 81A. The conductive layer 64B is electrically connected to the drain layer 11B of the switching device 1B via the plugs 81B.

The plug 65A is provided between the switching device 1A and the transistor 2A in the X direction. The plug 65A electrically connects the conductive layer 63A to the conductive layer 64A. The plug 65B is provided between the switching device 1B and the transistor 2B in the X direction. The plug 65B electrically connects the conductive layer 63B to the conductive layer 64B.

The transistor 2A is provided between the plugs 80 and the switching device 1A in the X direction. The transistor 2A is provided above the conductive layer 63A via the plug 86A in the Z direction. The source layer 22A of the transistor 2A is electrically connected to the conductive layer 90 of the high-side voltage node NdVDC+ via the conductive layer 93 and the plugs 80 and 85A. The drain layer 21A of the transistor 2A is electrically connected to the conductive layer 63A via the plug 86A. The drain layer 21A of the transistor 2A is electrically connected to the drain layer 11A of the switching device 1A via the conductive layers 63A and 64A and the plugs 65A, 81A, and 86A.

The transistor 2B is provided between the plugs 84 and the switching device 1B in the X direction. The transistor 2B is provided above the conductive layer 63B via the plugs 86B in the Z direction. The source layer 22B of the transistor 2B is electrically connected to the conductive layer 91 of the switching node NdVSW via the conductive layer 95A and the plugs 84 and 85B. The drain layer 21B of the transistor 2B is electrically connected to the conductive layer 63B via the plugs 86B. The drain layer 21B of the transistor 2B is electrically connected to the drain layer 11B of the switching device 1B via the conductive layers 63B and 64B and the plugs 65B, 81B, and 86B.

The switching device 1A may be provided above the conductive layer 63A via a plugs 83A instead of being provided above the conductive layer 90. The switching device 1B may be provided above the conductive layer 63B via the plugs 83B instead of being provided above the conductive layer 92.

In the semiconductor device 100 of the present modification, the high-side switching device 1 of the power module 100 is provided above the conductive layer 90 different from the conductive layer 91 of the switching node NdVSW of the power module 100.

Therefore, the semiconductor device 100 of the present modification can obtain substantially the same effects as the effects of the above-described embodiments.

### (8) Others

The semiconductor device of the embodiment may be a device other than a power module. The semiconductor device of the embodiment may be used in an electric apparatus (for example, an inverter) other than a converter.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductive layer provided on a substrate;
a second conductive layer provided on the substrate and to which a first voltage is supplied;
a third conductive layer corresponding to an output node and provided on the substrate between the first conductive layer and the second conductive layer;
a first switching device provided above the first conductive layer and including a first terminal to which a second voltage higher than the first voltage is supplied and a second terminal connected to the third conductive layer; and
a second switching device provided above the second conductive layer and including a third terminal connected to the third conductive layer and a fourth terminal connected to the second conductive layer.

2. The semiconductor device according to claim 1, further comprising:
a first transistor provided on the third conductive layer;
a second transistor provided on the second conductive layer;
a fourth conductive layer provided above the first switching device and the first transistor; and
a fifth conductive layer provided above the second switching device and the second transistor,
wherein
the first transistor includes a fifth terminal connected to the second terminal via the fourth conductive layer and a sixth terminal connected to the third conductive layer, and
the second transistor includes a seventh terminal connected to the fourth terminal via the fifth conductive layer and an eighth terminal connected to the second conductive layer.

3. The semiconductor device according to claim 2, wherein
the first and second switching devices are normally-on transistors containing gallium nitride.

4. The semiconductor device according to claim 3, wherein
the first and second transistors are normally-off transistors.

5. The semiconductor device according to claim 1, further comprising:
a sixth conductive layer provided above the first and second switching devices, wherein
the second and third terminals are connected to the third conductive layer via the sixth conductive layer.

6. The semiconductor device according to claim 1, wherein
the second voltage is supplied to the first conductive layer, and
the first terminal is connected to the first conductive layer.

7. The semiconductor device according to claim 1, further comprising:
a seventh conductive layer provided on the substrate and to which the second voltage is supplied,
wherein
the seventh conductive layer is connected to the first terminal,
the first conductive layer is continuous with the second conductive layer, and
the first voltage is supplied to the first conductive layer.

8. The semiconductor device according to claim 6, further comprising:
a portion that connects the first conductive layer to the second conductive layer,
wherein
the third conductive layer is provided between the first conductive layer and the second conductive layer in a first direction parallel to a surface of the substrate, and
the portion is adjacent to the third conductive layer in a second direction parallel to the surface of the substrate and intersecting the first direction.

9. The semiconductor device according to claim 1, further comprising:
an eighth conductive layer provided above the first switching device and to which the second voltage is supplied; and
a ninth conductive layer provided above the second switching device and connected to the second conductive layer.

10. The semiconductor device according to claim 9, further comprising:
a capacitor provided on the eighth and ninth conductive layers.

11. The semiconductor device according to claim 9, wherein
the ninth conductive layer overlaps the second conductive layer in a direction perpendicular to the surface of the substrate.

12. The semiconductor device according to claim 1, wherein
the substrate is a lead frame.

13. The semiconductor device according to claim 12, further comprising:
a capacitor provided on the first and second conductive layers.

14. The semiconductor device according to claim 1, wherein
each of the first and second conductive layers is a heat sink.

15. The semiconductor device according to claim 1, further comprising:
one or more first conductors provided between the first conductive layer and a back surface of the first switching device; and
one or more second conductors provided between the second conductive layer and a back surface of the second switching device.

16. A semiconductor device comprising:
a first conductive layer provided on a substrate and to which a second voltage is supplied;
a second conductive layer provided on the substrate and to which a first voltage lower than the second voltage is supplied;
a third conductive layer corresponding to an output node and provided on the substrate between the first conductive layer and the second conductive layer;
a tenth conductive layer provided on the substrate between the first conductive layer and the third conductive layer;
a first switching device provided above the tenth conductive layer and including a first terminal and a second terminal connected to the third conductive layer;
a second switching device provided above the second conductive layer and including a third terminal and a fourth terminal connected to the second conductive layer;
an eleventh conductive layer provided on the substrate between the first conductive layer and the fourth conductive layer, the eleventh conductive layer connected to the first terminal;
a first transistor provided above the eleventh conductive layer and including a fifth terminal connected to the first conductive layer and a sixth terminal connected to the eleventh conductive layer;
a sixth conductive layer provided on the substrate between the second conductive layer and the third conductive layer, the sixth conductive layer connected to the third terminal;
a second transistor provided above the sixth conductive layer and including a seventh terminal connected to the third conductive layer and an eighth terminal connected to the sixth conductive layer;
a seventh conductive layer provided above the first switching device and the first transistor; and
a ninth conductive layer provided above the second switching device and the second transistor.

17. The semiconductor device according to claim 16, further comprising:
a capacitor provided on the seventh and ninth conductive layers.

18. The semiconductor device according to claim 16, wherein
each of the second and fourth conductive layers is a heat sink.

19. The semiconductor device according to claim 16, further comprising:
one or more first conductors provided between the tenth conductive layer and a back surface of the first switching device; and
one or more second conductors provided between the second conductive layer and a back surface of the second switching device.
